(19) United States
(12) Patent Application Publication
(10) Pub. No.: US 2016/0239145 A1
(43) Pub. Date: Aug. 18, 2016

(54) TOUCH BUTTON SYSTEM HAVING EXTERNALLY PROGRAMMABLE DISPLAY

(71) Applicant: YICHENG PRECISION INC., Tainan City (TW)

(72) Inventors: Jen-Chieh CHANG, Taipei City (TW); Chung-Lin CHIA, Taipei City (TW); Han-Chang CHEN, Taipei City (TW); Yen-Hung TU, Taipei City (TW); Chih-Wen WU, Taipei City (TW)

(21) Appl. No.: 14/972,751

(22) Filed: Dec. 17, 2015

(30) Foreign Application Priority Data
Feb. 13, 2015 (TW) 104104966

(51) Int. Cl. G06F 3/041; H03K 17/96; G06F 3/02; H01H 23/02; G06F 3/0484; G06F 3/0488; H01H 13/50

(52) U.S. Cl. CPC G06F 3/0416; G06F 3/04886; H03K 17/9618; H01H 13/50; H01H 23/02; G06F 3/04847; G06F 3/04842; G06F 3/04883; G06F 3/0227

(57) ABSTRACT

A touch button system having externally programmable display, including: at least one touch display button, each having a touch display area, a button operation data output interface, and a display data input interface; and a control unit, including at least one touch display interface, at least one input interface, and at least one output interface, wherein, the at least one touch display interface is coupled with the display data input interface and the button operation data output interface of the at least one touch display button for transmitting display data and deriving button operation data; the at least one input interface is used for receiving image data from an external device, and the control unit generates the display data according to the image data; and the at least one output interface is used for outputting at least one operation code.

### BACKGROUND OF THE INVENTION

1. Field of the Invention

The present invention relates to a button system, especially to a touch button system having externally programmable display.

2. Description of the Related Art

Please refer to FIG. 1a, which illustrates an outline of a button with display of prior art; and FIG. 1b, which illustrates a block diagram of the internal circuit of the button with display of prior art. As illustrated in FIG. 1a, the button with display of prior art includes a mechanical button 10 and a display 20, and as illustrated in FIG. 1b, the internal circuit includes a micro controller 11, a display controller 12, and a serial peripheral interface (SPI) 13.

The display controller 12 drives the display 20 to display a user interface according to pre-stored display data. When the button with display of prior art is pressed, the micro controller 11 can provide detected information to an external device via the SPI 13.

However, when the number of mechanical connections of the mechanical button increases, the reliability of the button with display of prior art will decrease. Besides, when the user interface is to be changed, the button with display will need to connect and communicate with a program development kit to reload display data of another user interface, which causes much inconvenience.

To solve the foregoing problems, a novel button system is needed.

### SUMMARY OF THE INVENTION

One objective of the present invention is to disclose a touch button system having externally programmable display, which is capable of using less mechanical switch contacts.

Another objective of the present invention is to disclose a touch button system having externally programmable display, which is capable of updating a display on-line.

Another objective of the present invention is to disclose a touch button system having externally programmable display, which is capable of providing both a long operational life and a mechanical touch.

Another objective of the present invention is to disclose a touch button system having externally programmable display, which is capable of using a small operation area to provide multiple operation functions.

Still another objective of the present invention is to disclose a touch button system having externally programmable display, which is capable of assigning different priority levels to button operations at different locations so that the button operation for the most urgent scenario can be addressed first.

To attain the foregoing objectives, a touch button system having externally programmable display is proposed, including:
at least one touch display button, each having a touch display area, a button operation data output interface, and a display data input interface; and
a control unit, including at least one touch display interface, at least one input interface, and at least one output interface, wherein, the at least one touch display interface is coupled with the display data input interface and the button operation data output interface of the at least one touch display button for transmitting display data to and deriving button operation data from each of the at least one touch display button; the at least one input interface is used for receiving image data from an external device, and the control unit generates the display data according to the image data; and the at least one output interface is used for outputting at least one operation code, the at least one operation code being generated according to the button operation data.

In one embodiment, the touch display area of each of the at least one touch display button includes a display layer and a touch sensing layer, the display layer being selected from a group consisting of a liquid crystal display layer, an organic light emitting diode display layer, a polymer light emitting diode display layer, and an electronic paper display layer, and the touch sensing layer being glued to or integrated with the display layer.

In one embodiment, the touch display area of each of the at least one touch display button includes a display layer and a touch sensing layer, the display layer being selected from a group consisting of a liquid crystal display layer, an organic light emitting diode display layer, a polymer light emitting diode display layer, and an electronic paper display layer, and the touch sensing layer being embedded in the display layer or implemented by display electrodes of the display layer.

In one embodiment, at least one of the at least one touch display button includes a mechanical switch, and the mechanical switch is selected from a group consisting of a pushbutton switch, a rocker switch, a band switch, and any combination thereof

In one embodiment, the image data is for displaying characters, symbols, figures, or images.

In one embodiment, the operation code includes at least one identification code for at least one of the at least one touch display button.

In one embodiment, the operation code carries information of a touch operation, a dialing operation, or a press operation performed on at least one of the at least one touch display button.

In one embodiment, the operation code includes a control code generated according to a hybrid operation on at least one of the at least one touch display button, the hybrid operation being a combination of a touch operation and a press operation, a combination of a touch operation and a dialing operation, or a combination of a touch operation, a dialing operation, and a press operation.

In one embodiment, the at least one touch display button is located on a dashboard of a vehicle for a user to perform a hybrid operation to select and execute a function option, the hybrid operation being a touch operation, a combination of a touch operation and a gesture operation, a combination of a touch operation and a press operation, a combination of a touch operation and a dialing operation, or a combination of a touch operation, a dialing operation, and a press operation.

To attain the foregoing objectives, another touch button system having externally programmable display is proposed, including:
a plurality of touch units, each including:
at least one touch display button, each having a touch display area, a button operation data output interface, and a display data input interface; and
a control unit, including at least one touch display interface, at least one input interface, and at least one output interface, wherein, the at least one touch display interface is coupled with the display data input interface and the button operation data output interface of the at least one touch display button for transmitting display data to and deriving button operation data from each of the at least one touch display button; the at least one input interface is used for receiving image data from an external device, and the control unit generates the display data according to the image data; and the at least one output interface is used for outputting at least one operation code, the at least one operation code being generated according to the button operation data; and
a central processing unit coupled with the control unit of each of the touch units to provide the image data and receive the at least one operation code, and drive at least one object in response to the at least one operation code in a prioritized order.

To make it easier for our examiner to understand the objective of the invention, its structure, innovative features, and performance, we use preferred embodiments together with the accompanying drawings for the detailed description of the invention.

### BRIEF DESCRIPTION OF THE DRAWINGS

FIG. 1a illustrates an outline of a button with display of prior art.

FIG. 1b illustrates a block diagram of the internal circuit of the button with display of prior art of FIG. 1a.

FIG. 2 illustrates an embodiment of a touch button system having externally programmable display of the present invention.

FIG. 3 illustrates another embodiment of a touch button system having externally programmable display of the present invention.

FIG. 4a illustrates an application of a touch display button of the present invention on a dashboard of a vehicle.

FIG. 4b-4d illustrate three air outlet options selected by a user operating on the touch display button of FIG. 4a with a dragging gesture.

FIG. 5a illustrates another application of a touch display button of the present invention on a dashboard of a vehicle.

FIG. 5b-5d illustrate three air outlet options selected by a user operating on the touch display button of FIG. 5a with a dialing gesture.

FIG. 5e illustrates an inside air mode selected by a user operating on the touch display button of FIG. 5a with a touch.

FIG. 5f illustrates an outside air mode selected by a user operating on the touch display button of FIG. 5a with a touch.

FIG. 6a illustrates still another application of a touch display button of the present invention on a dashboard of a vehicle.

FIG. 6b illustrates a dragging operation by a user on the touch display button of FIG. 6a to set a lower temperature.

FIG. 6c illustrates a dragging operation by a user on the touch display button of FIG. 6a to set a higher temperature.

FIG. 6d-6f illustrate different air volumes selected by a user operating on the touch display button of FIG. 6a with a dialing gesture.

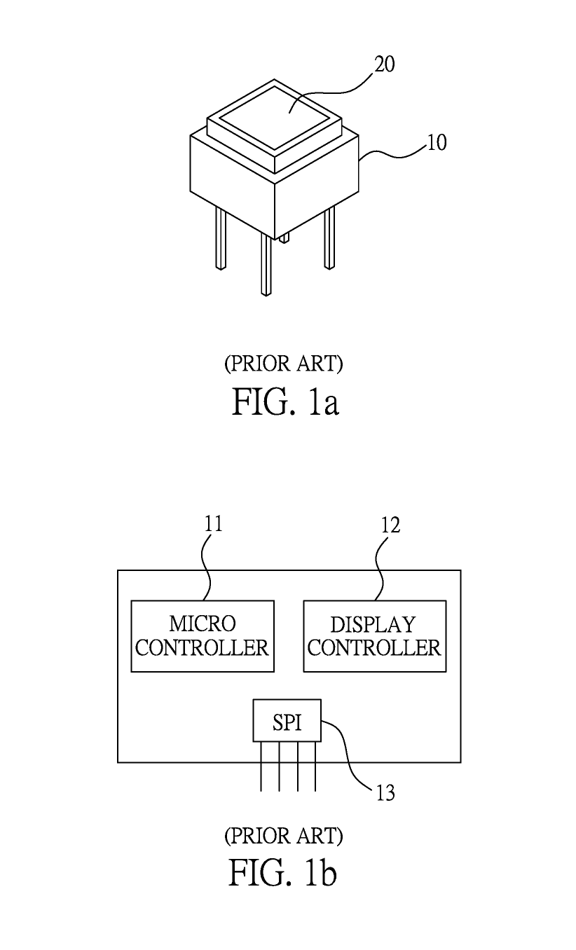

### DETAILED DESCRIPTION OF THE PREFERRED EMBODIMENTS

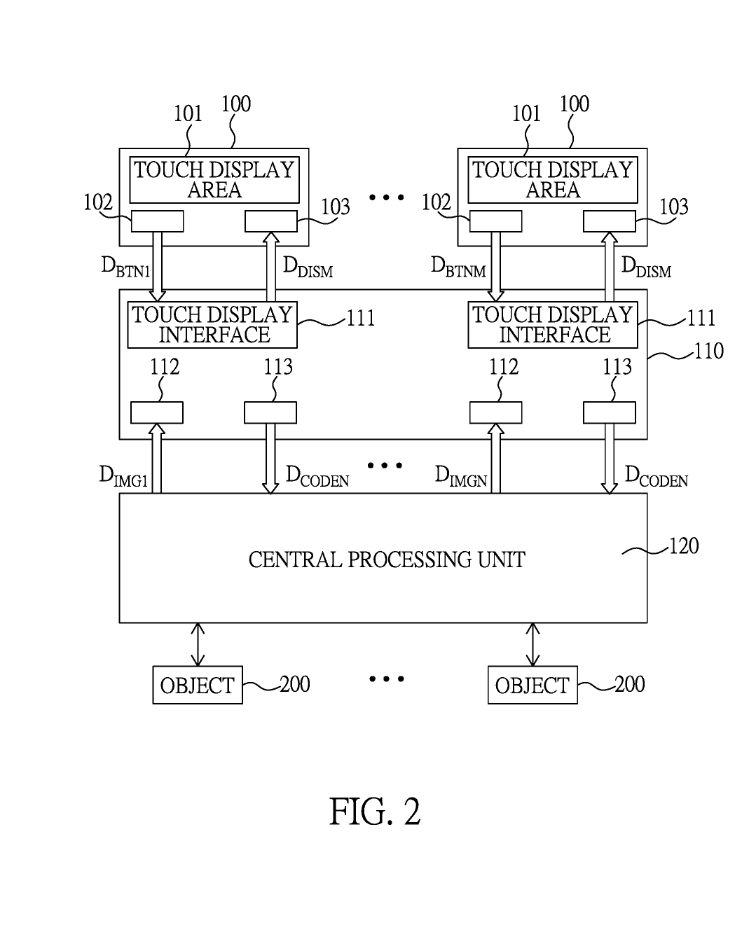

Please refer to FIG. 2, which illustrates an embodiment of a touch button system having externally programmable display of the present invention. As illustrated in FIG. 2, the touch button system includes at least one touch display button 100, a control unit 110, and a central processing unit 120.

The touch display button 100 has a touch display area 101, a button operation data output interface 102, and a display data input interface 103. The touch display area 101 includes a display layer and a touch sensing layer (not shown in the figure), the display layer can be a liquid crystal display layer, an organic light emitting diode display layer, a polymer light emitting diode display layer, or an electronic paper display layer, and the touch sensing layer can be glued to or integrated with the display layer, embedded in the display layer or implemented by display electrodes of the display layer.

Besides, the touch display button 100 can further include a mechanical switch, and the mechanical switch can be a pushbutton switch, a rocker switch, a band switch, or any combination of the mentioned switches.

The control unit 110 includes at least one touch display interface 111, at least one input interface 112, and at least one output interface 113, wherein, the at least one touch display interface 111 is coupled with the display data input interface 103 and the button operation data output interface 102 of the at least one touch display button 100 for transmitting display data D_{DIS1}-D_{DISM} to and deriving button operation data D_{BTN1}-D_{BTNM} from each of the at least one touch display button 100; the at least one input interface 112 is used for receiving image data D_{IMG1}-D_{IMGN} from an external device, and the control unit 110 generates the display data D_{DIS1}-D_{DISM} according to the image data D_{IMG1}-D_{IMGN}; and the at least one output interface 113 is used for outputting at least one operation code D_{COD1}-D_{CODEN}, the at least one operation code D_{CODE1}-D_{CODEN} being generated according to the button operation data D_{BTN1}-D_{BTNM}. The image data D_{IMG1}-D_{IMGN} can be for displaying characters, symbols, figures, or images. When the image data D_{IMG1}-D_{IMGN} are for displaying images, an operator can see a real time image of a monitored scene on a touch display area.

The operation code D_{CODE1}-D_{CODEN} can include at least one identification code for at least one of the at least one touch display button 100, or a control code generated according to a hybrid operation. The operation code D_{CODE1}-D_{CODEN} can carry information of a touch operation, a dialing operation (where a user performs a gesture operation on a touch plane or rotates a band switch), or a press operation (where a user presses a pushbutton switch or a rocker switch) on at least one of the at least one touch display button 100. The hybrid operation can be a combination of a touch operation and a press operation, a combination of a touch operation and a dialing operation, or a combination of a touch operation, a dialing operation, and a press operation.

The central processing unit 120 is coupled with the at least one input interface 112 and the at least one output interface 113 of the control unit 110 to provide the image data D_{IMG1}-D_{IMGN} and receive the at least one operation code D_{CODE1}-D_{CODEN}, and drive at least one object 200 in response to the at least one operation code D_{CODE1}-D_{CODEN}. Besides, the central processing unit 120 can communicate with the control unit 110 in a wired manner, such as using I²C (Inter-Integrated Circuit), SPI (Serial Peripheral Interface), AV (Audio Video), LVDS (Low Voltage Differential Signaling), HDMI (High Definition Multimedia Interface), USB(Universal Serial Bus), PCI (Peripheral Component Interconnect), Net, or Canbus (Controller area network bus); or in a wireless manner, such as using WiFi or Bluetooth.

Besides, the central processing unit 120 can also be coupled with the control units 110 at different locations (via internet, for example) to receive button operations from different locations, and the central processing unit 120 can prioritize the button operations from different locations so that the button operation for the most urgent scenario can be addressed first.

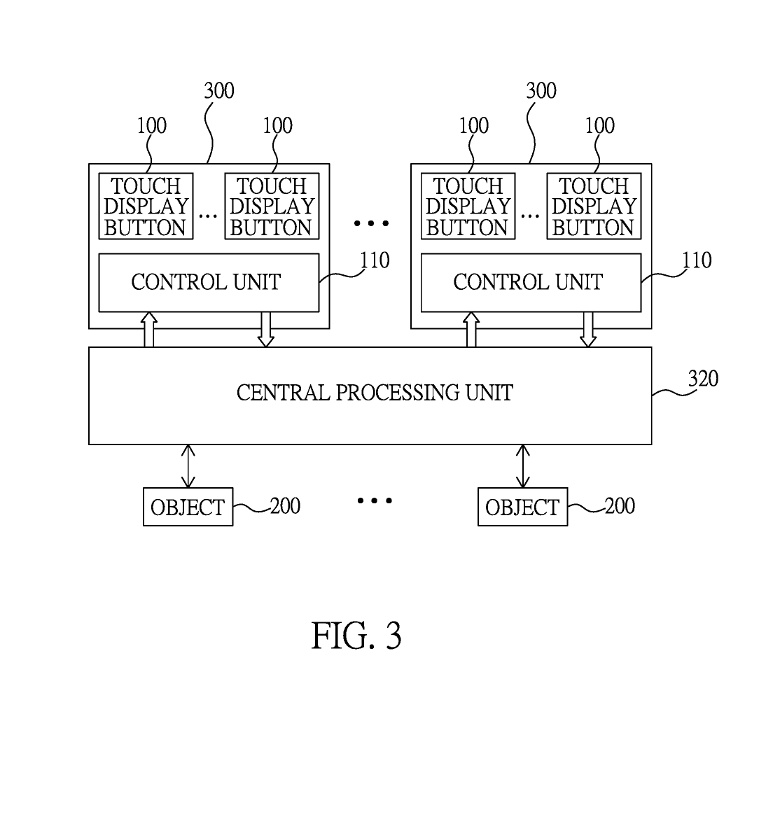

Please refer to FIG. 3, which illustrates another embodiment of a touch button system having externally programmable display of the present invention. As illustrated in FIG. 3, the touch button system includes a plurality of touch units 300 and a central processing unit 320, wherein the touch unit 300 includes at least one touch display button 100 and a control unit 110. As the functions of the touch display button 100 and the control unit 110 have been described above with reference to FIG. 2, they will not be readdressed.

The central processing unit 320 is coupled with the control units 110 to provide the image data and receive the operation codes, and drives at least one object 200 in response to the operation codes in a prioritized order.

Besides, the touch button system of the present invention can be applied to a vehicle so that a user can perform a hybrid operation (the hybrid operation can be a combination of a touch operation and a press operation, a combination of a touch operation and a dialing operation, or a combination of a touch operation, a dialing operation, and a press operation) on the touch display buttons to select and execute a function option.

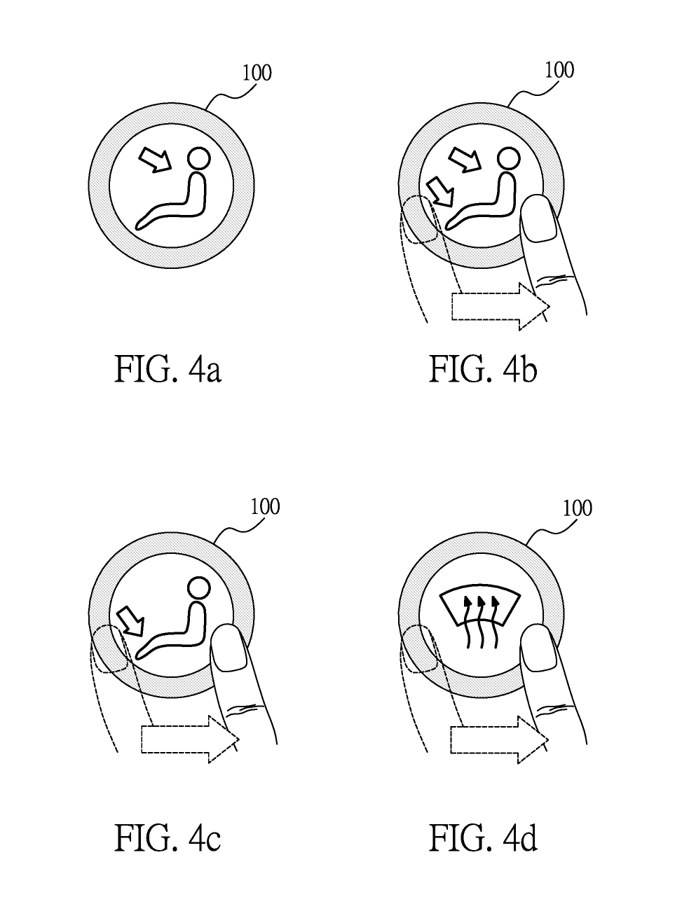

Please refer to FIG. 4a, which illustrates an application of the touch display button of the present invention on a dashboard of a vehicle. A user can perform a dragging operation on the touch display button of FIG. 4a to select an air outlet (as the selected outlets illustrated in FIG. 4b-4d). Compared to conventionally using a mechanical dial or pushbutton to select an air outlet, the touch gesture operation of the present invention is obviously a much more convenient way for a user.

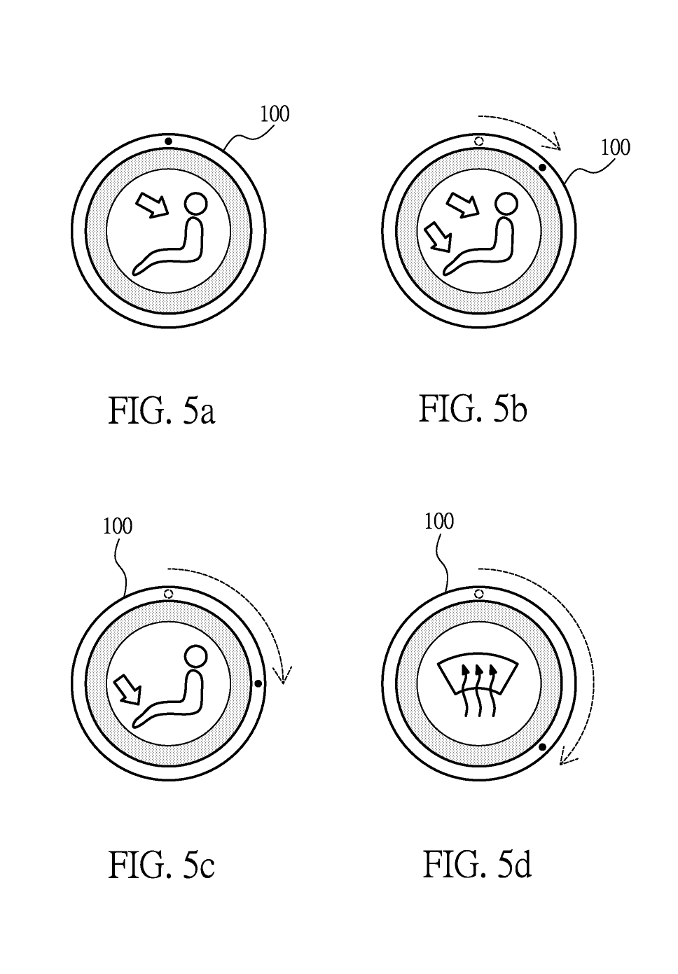

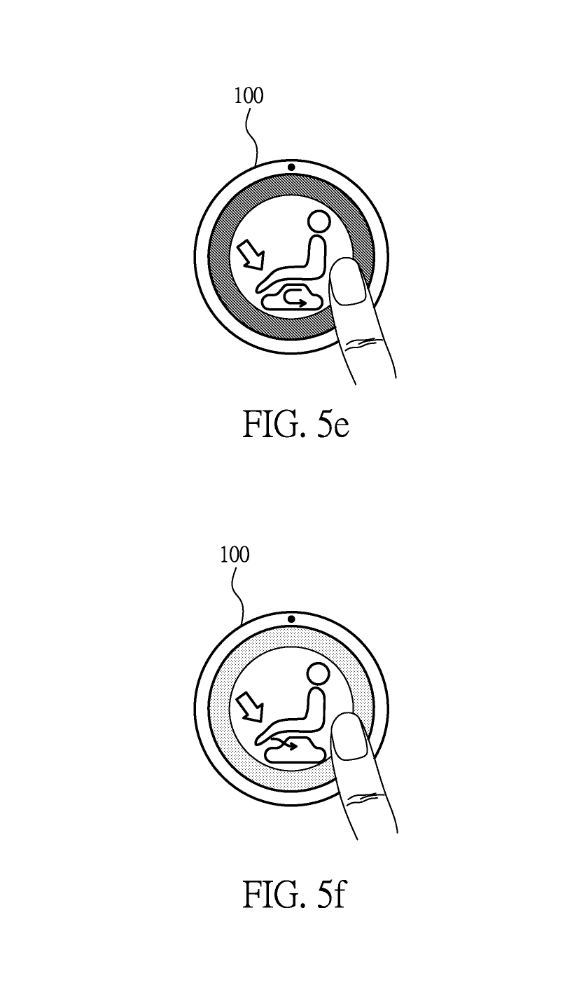

Please refer to FIG. 5a, which illustrates another application of the touch display button of the present invention on a dashboard of a vehicle. A user can perform a dialing operation on the touch display button of FIG. 5a to select an air outlet (as the selected outlets illustrated in FIG. 5b-5d), or perform a touch operation on the touch display button to select an air circulation mode (as illustrated in FIG. 5e-5f, wherein, an inside air mode is selected in FIG. 5e and an outside air mode is selected in FIG. 5f). Besides, the touch display button of FIG. 5a can be implemented solely by a touch button or by a touch sensing layer and a band switch.

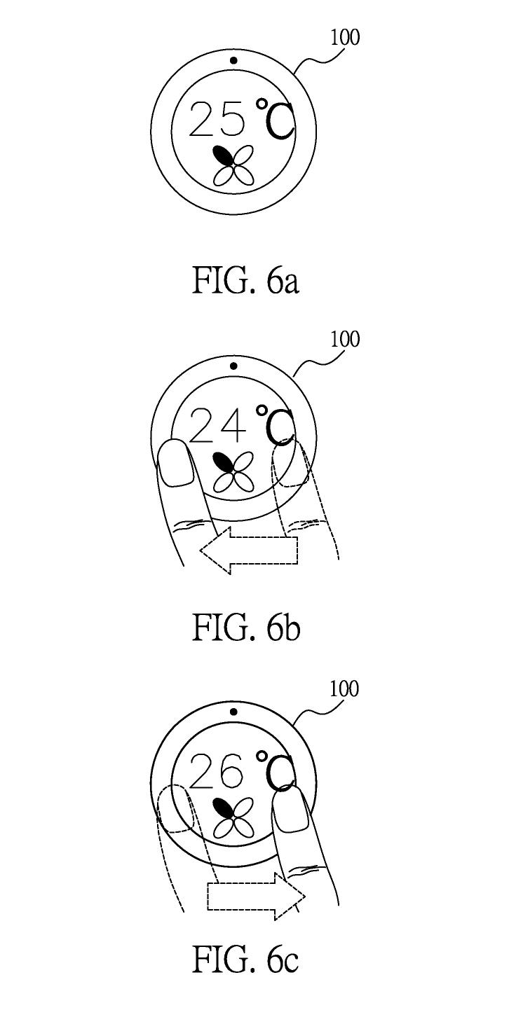

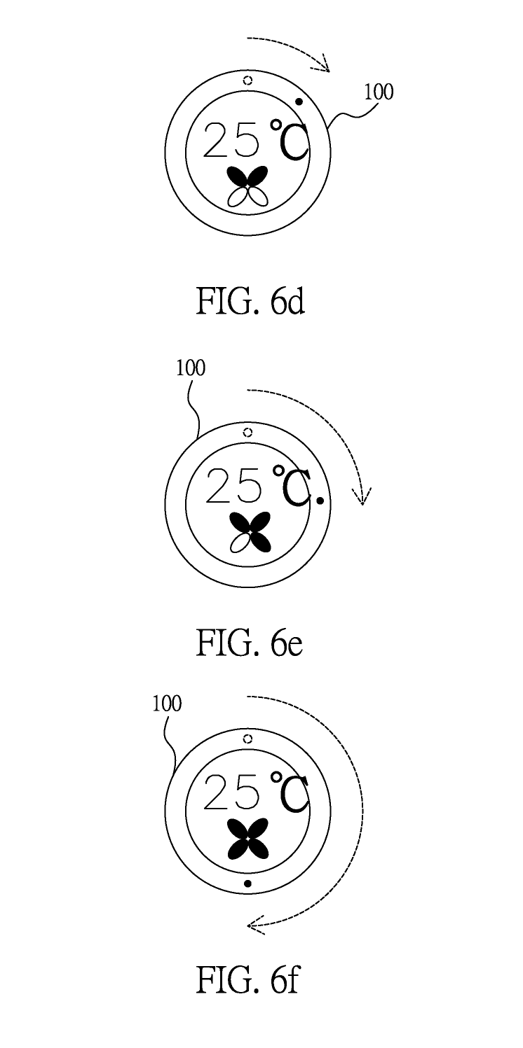

Please refer to FIG. 6a, which illustrates still another application of the touch display button of the present invention on a dashboard of a vehicle. A user can perform a dragging operation on the touch display button of FIG. 6a to set a lower temperature (as illustrated in FIG. 6b) or a higher temperature (as illustrated in FIG. 6c), or perform a dial operation on the touch display button to set different air volumes (as illustrated in FIG. 6d-6f). Besides, the touch display button of FIG. 6a can be implemented solely by a touch button or by a touch sensing layer and a band switch.

Thanks to the proposals above, the present invention possesses the following advantages:

1. The touch button system having externally programmable display of the present invention is capable of using less mechanical switch contacts.

2. The touch button system having externally programmable display of the present invention is capable of updating a display on-line.

3. The touch button system having externally programmable display of the present invention is capable of providing both a long operational life and a mechanical touch.

4. The touch button system having externally programmable display of the present invention is capable of using a small operation area to provide multiple operation functions.

5. The touch button system having externally programmable display of the present invention is capable of assigning different priority levels to button operations at different locations so that the button operation for the most urgent scenario can be addressed first.

While the invention has been described by way of example and in terms of preferred embodiments, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance than the conventional structure and further complies with the patent application requirements and is submitted to the Patent and Trademark Office for review and granting of the commensurate patent rights.

What is claimed is:

1. A touch button system having externally programmable display, including:
at least one touch display button, each having a touch display area, a button operation data output interface, and a display data input interface; and
a control unit, including at least one touch display interface, at least one input interface, and at least one output interface, wherein, the at least one touch display interface is coupled with the display data input interface and the button operation data output interface of the at least one touch display button for transmitting display data to and deriving button operation data from each of the at least one touch display button; the at least one input interface is used for receiving image data from an external device, and the control unit generates the display data according to the image data; and the at least one output interface is used for outputting at least one operation code, the at least one operation code being generated according to the button operation data.

2. The touch button system having externally programmable display as disclosed in claim 1, wherein the touch display area of each of the at least one touch display button includes a display layer and a touch sensing layer, the display layer being selected from a group consisting of a liquid crystal display layer, an organic light emitting diode display layer, a polymer light emitting diode display layer, and an electronic paper display layer, and the touch sensing layer being glued to or integrated with the display layer.

3. The touch button system having externally programmable display as disclosed in claim 1, wherein the touch display area of each of the at least one touch display button includes a display layer and a touch sensing layer, the display layer being selected from a group consisting of a liquid crystal display layer, an organic light emitting diode display layer, a polymer light emitting diode display layer, and an electronic paper display layer, and the touch sensing layer being embedded in the display layer or implemented by display electrodes of the display layer.

4. The touch button system having externally programmable display as disclosed in claim 1, wherein at least one of the at least one touch display button includes a mechanical switch, and the mechanical switch is selected from a group consisting of a pushbutton switch, a rocker switch, a band switch, and any combination thereof.

5. The touch button system having externally programmable display as disclosed in claim 1, wherein the image data is for displaying characters, symbols, figures, or images.

6. The touch button system having externally programmable display as disclosed in claim 1, wherein the operation code includes at least one identification code for at least one of the at least one touch display button.

7. The touch button system having externally programmable display as disclosed in claim 1, wherein the operation code carries information of a touch operation, a dialing operation, or a press operation performed on at least one of the at least one touch display button.

8. The touch button system having externally programmable display as disclosed in claim 1, wherein the operation code includes a control code generated according to a hybrid operation on at least one of the at least one touch display button, the hybrid operation being a combination of a touch operation and a press operation, a combination of a touch operation and a dialing operation, or a combination of a touch operation, a dialing operation, and a press operation.

9. The touch button system having externally programmable display as disclosed in claim 1, wherein the at least one touch display button is located on a dashboard of a vehicle for a user to perform a hybrid operation to select and execute a function option, the hybrid operation being a touch operation, a combination of a touch operation and a gesture operation, a combination of a touch operation and a press operation, a combination of a touch operation and a dialing operation, or a combination of a touch operation, a dialing operation, and a press operation.

10. A touch button system having externally programmable display, including:
a plurality of touch units, each including:
at least one touch display button, each having a touch display area, a button operation data output interface, and a display data input interface; and
a control unit, including at least one touch display interface, at least one input interface, and at least one output interface, wherein, the at least one touch display interface is coupled with the display data input interface and the button operation data output interface of the at least one touch display button for transmitting display data to and deriving button operation data from each of the at least one touch display button; the at least one input interface is used for receiving image data from an external device, and the control unit generates the display data according to the image data; and the at least one output interface is used for outputting at least one operation code, the at least one operation code being generated according to the button operation data; and
a central processing unit coupled with the control unit of each of the touch units to provide the image data and receive the at least one operation code, and drive at least one object in response to the at least one operation code in a prioritized order.
